(19) United States
(12) Patent Application Publication
(10) Pub. No.: US 2023/0413539 A1
(43) Pub. Date: Dec. 21, 2023

(54) SEMICONDUCTOR STRUCTURE AND SEMICONDUCTOR MEMORY

(71) Applicant: CHANGXIN MEMORY TECHNOLOGIES, INC., Hefei (CN)

(72) Inventor: LING-YI CHUANG, Hefei (CN)

(21) Appl. No.: 18/152,158

(22) Filed: Jan. 10, 2023

(30) Foreign Application Priority Data
May 26, 2022 (CN) 202210583157.6

(51) Int. Cl. H10B 12/00

(52) U.S. Cl. CPC H10B 12/488; H10B 12/315

(57) ABSTRACT

Embodiments provide a semiconductor structure and a semiconductor memory, relating to the field of semiconductor technology. The semiconductor structure includes a substrate, active pillars spaced on the substrate, word lines spaced on the substrate along a second direction, and a dielectric layer covering the active pillars and the word lines. Each of the word lines extends along a first direction and is connected to the active pillars positioned in the first direction. In any adjacent two word lines, a groove is provided on a surface of at least one of the two adjacent word lines towards other one of the two adjacent word lines, and an air gap is provided in the dielectric layer positioned between adjacent word lines.

### CROSS-REFERENCE TO RELATED APPLICATION

This application claims priority to Chinese Patent Application No. 202210583157.6, titled “SEMICONDUCTOR STRUCTURE AND SEMICONDUCTOR MEMORY” and filed to the State Patent Intellectual Property Office on May 26, 2022, the entire contents of which are incorporated herein by reference.

### TECHNICAL FIELD

Embodiments of the present disclosure relate to the field of semiconductor technology, and more particularly, to a semiconductor structure and a semiconductor memory.

### BACKGROUND

As a semiconductor memory that randomly writes and reads data at a high speed, a dynamic random access memory (DRAM) is widely used in data storage devices or apparatuses. In general, the DRAM includes a plurality of memory cells, each of which generally includes a capacitor and a transistor, where a gate of the transistor is electrically connected to a word line (WL for short), and one of a source and a drain of the transistor is electrically connected to a bit line (BL for short).

However, with the development of the DRAM towards integration, a larger parasitic capacitance is generated between adjacent word lines, which reduces performance of the DRAM.

### SUMMARY

In view of the above problem, embodiments of the present disclosure provide a semiconductor structure and a semiconductor memory.

An embodiment of the present disclosure provides a semiconductor structure, which includes: a substrate; and a plurality of active pillars spaced on the substrate, each of the plurality of active pillars extending along a direction perpendicular to the substrate; a plurality of word lines spaced on the substrate along a second direction, each of the plurality of word lines extending along a first direction, wherein the first direction intersects with the second direction, each of the plurality of word lines being connected to a given one of the plurality of active pillars positioned in the first direction; and in any adjacent two of the plurality of word lines, a groove is provided in a surface of at least one of the two adjacent word lines towards other one of the two adjacent word lines, the groove penetrating through the word line along the direction perpendicular to the substrate; and a dielectric layer arranged on the substrate and covering the plurality of active pillars and the plurality of word lines; wherein an air gap is provided in the dielectric layer positioned between adjacent two of the plurality of word lines.

### BRIEF DESCRIPTION OF THE DRAWINGS

To describe the technical solutions of the embodiments of the present disclosure or those of the prior art more clearly, the accompanying drawings required for describing the embodiments or the prior art will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram I of a semiconductor structure according to an embodiment of the present disclosure;

FIG. 2 is a sectional view along an A-A direction in FIG. 1;

FIG. 3 is a sectional view along a B-B direction in FIG. 1;

FIG. 4 is a schematic diagram II of the semiconductor structure according to an embodiment of the present disclosure;

FIG. 5 is a schematic diagram I of a word line according to an embodiment of the present disclosure;

FIG. 6 is a schematic diagram II of the word line according to an embodiment of the present disclosure;

FIG. 7 is a schematic diagram III of the semiconductor structure according to an embodiment of the present disclosure;

FIG. 8 is a schematic diagram IV of the semiconductor structure according to an embodiment of the present disclosure; and

FIG. 9 is a schematic diagram of a capacitor according to an embodiment of the present disclosure.

Reference numerals in the accompanying drawings:
10: substrate; 11: well region; 12: shallow trench isolation structure; 20: active pillar; 21: channel region; 22: source region; 23: drain region; 30: word line; 31: first segment; 32: second segment; 321: first surface; 322: second surface; 33: groove; 40: dielectric layer; 41: air gap; 50: bit line; 60: capacitor; 61: first electrode; 62: first dielectric layer; 63: second electrode; and 70: gate oxide layer.

### DETAILED DESCRIPTION

As mentioned in the background art, a semiconductor structure in the related technologies has a larger parasitic capacitance. Based on research, it is found that reasons for this problem lie in that with continuously increasing integration level of the semiconductor structure, spacing between semiconductor devices is getting smaller and smaller. For example, the parasitic capacitance is formed between adjacent word lines, and the parasitic capacitance is directly proportional to a dielectric constant of a dielectric layer between the adjacent word lines and is inversely proportional to a pitch between the adjacent word lines. In this way, with decrease of the pitch between the adjacent word lines, the parasitic capacitance increases continuously, thereby increasing a risk of signal interference between the adjacent word lines, and degrading performance of the semiconductor structure.

In view of the above technical problem, embodiments of the present disclosure provide a semiconductor structure and a semiconductor memory. A groove is provided on a surface of at least one of any two adjacent word lines towards other one of the two adjacent word lines, such that the pitch between the two adjacent word lines is increased, thereby reducing the parasitic capacitance between the adjacent word lines, and improving the performance of the semiconductor structure.

In addition, an air gap is provided in the dielectric layer positioned between the adjacent word lines to reduce the dielectric constant of the dielectric layer positioned between the adjacent word lines, thereby reducing the parasitic capacitance between the adjacent word lines, and improving the performance of the semiconductor structure.

To make the above objectives, features, and advantages of the embodiments of the present disclosure more apparent and lucid, the technical solutions in the embodiments of the present disclosure will be described clearly and completely below with reference to the accompanying drawings in the embodiments of the present disclosure. Apparently, the described embodiments are merely some but not all of the embodiments of the present disclosure. All other embodiments obtained by persons of ordinary skill in the art based on the embodiments of the present disclosure without creative efforts shall fall within the protection scope of the present disclosure.

This embodiment does not impose restrictions on the semiconductor structure, and an introduction will be made below by taking an example where the semiconductor structure is a dynamic random access memory (DRAM), but this embodiment is not limited thereto, and the semiconductor structure in this embodiment may also be other structures.

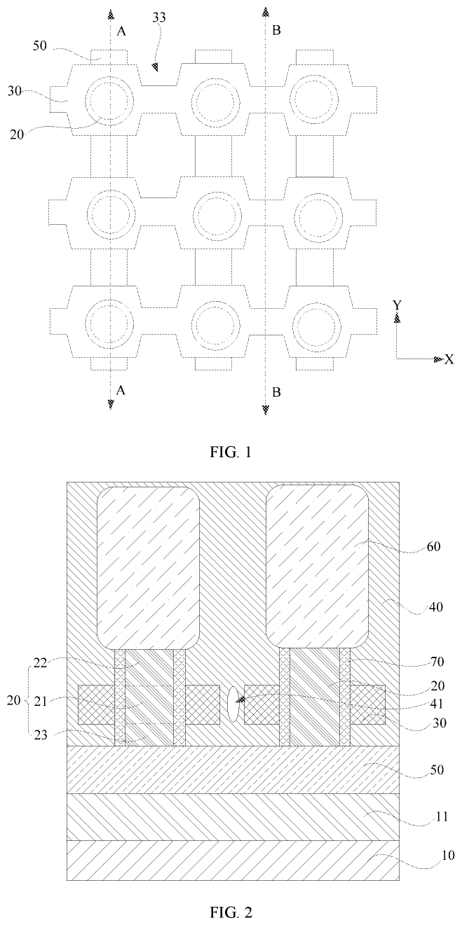

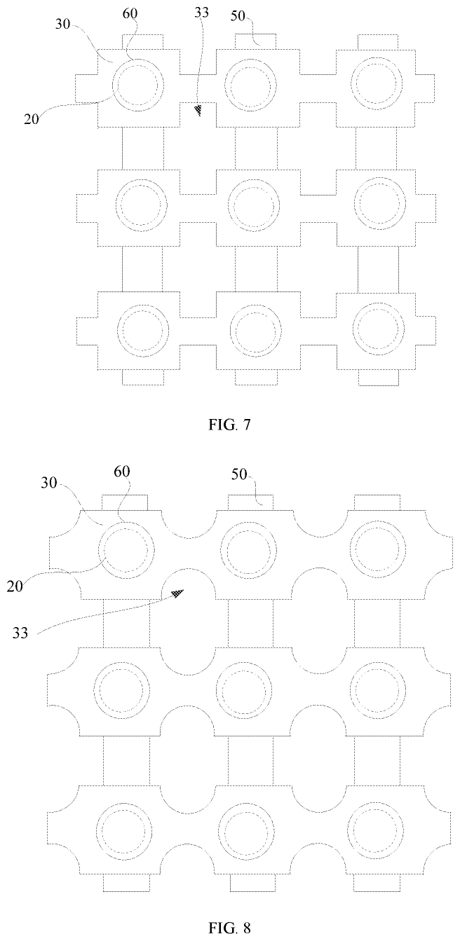

Referring to FIG. 1 to FIG. 9, a semiconductor structure provided by an embodiment of the present disclosure includes a substrate 10, a plurality of active pillars 20, a plurality of word lines 30 and a dielectric layer 40.

The substrate 10 is configured to support a semiconductor device disposed thereon, such as active pillars 20 and word lines 30. The substrate 10 may be a silicon (Si) substrate, a germanium (Ge) substrate, a silicon germanium (GeSi) substrate, a silicon carbide (SiC) substrate, a silicon on insulator (SOI) substrate or a germanium on insulator (GOI) substrate, etc.

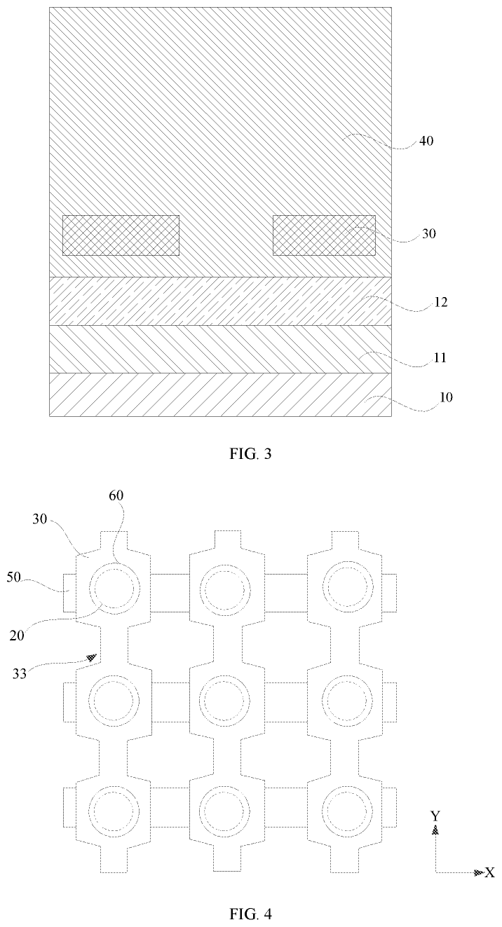

Referring to FIG. 2 and FIG. 3, the substrate 10 includes a well region 11. If a P-type region is diffused on an N-type semiconductor substrate, it is called a P-well region (P-well); and if an N-type region is diffused on a P-type semiconductor substrate, it is called an N-well region (N-well), which is not limited here. In some embodiments, a shallow trench isolation (STI) structure 12 may be disposed between the plurality of bit lines 50, and the plurality of bit lines 50 are separated by the STI structure 12 to ensure that the plurality of bit lines 50 are independent of each other and insulated from each other.

When forming the STI structure 12, a shallow trench may be formed in the substrate through a patterning process, and an insulating material may be filled in the shallow trench, thereby defining, in the substrate 10, a plurality of bit line to-be-formed regions separated by the STI structure 12. The patterning fabrication process may be a self-aligned double patterning (SADP) process or a self-aligned quadruple patterning (SAQP) process. The insulating material may be silicon oxide.

The plurality of active pillars 20 are arranged on the substrate 10 in a plurality of rows and columns. That is, the plurality of active pillars 20 are arranged in a regular rectangular array, where each of the active pillars 20 extends along a direction perpendicular to the substrate 10, to facilitate subsequent formation of a VGG transistor.

The plurality of word lines 30 are arranged on the substrate 10 at intervals along a second direction, and each of the word lines 30 extends along a first direction, where the first direction intersects the second direction, and each of the word lines 30 is connected to the active pillar 20 in the first direction.

In an example, referring to FIG. 1, the first direction may be understood as an X direction in FIG. 1, and the second direction may be understood as a Y direction in FIG. 1. Each of the word lines 30 extends along the first direction to connect all the active pillars 20 positioned in the same first direction.

In another example, referring to FIG. 4, the first direction may be understood as the Y direction in FIG. 4, and the second direction may be understood as the X direction in FIG. 4. Each of the word lines 30 extends along the first direction to connect all the active pillars 20 positioned in the same first direction. In this way, one word line 30 can control all the active pillars 20 in the same first direction, which improves control precision of the semiconductor structure.

In any adjacent two word lines 30, a groove 33 is provided on a surface of at least one of the two adjacent word lines 30 towards other one of the two adjacent word lines and the groove 33 penetrates through the word lines 30 along the direction perpendicular to the substrate 10. In an example, referring to FIG. 5, the groove 33 is provided on the surface of one word line 30 towards another word line 30. For example, in two adjacent word lines 30, from top to bottom, the groove 33 is provided on the surface of the first word line 30 towards the second word line 30. For another example, the groove 33 is provided on the surface of the second word line 30 towards the first word line 30.

In another example, with continued reference to FIG. 1, opposite surfaces of the two word lines 30 are both provided with the groove 33. Compared with the technical solution where surfaces of the word lines 30 are flat in the related technologies, the spacing between adjacent word lines 30 can be increased, the parasitic capacitance between the adjacent word lines 30 can be reduced, and the parasitic capacitance of the semiconductor structure can be reduced.

With continued reference to FIG. 2, the semiconductor structure further includes a dielectric layer 40. The dielectric layer 40 is disposed on the substrate 10 and covers the plurality of active pillars 20 and the plurality of word lines 30. In this way, insulation between the plurality of active pillars 20 and the plurality of word lines 30 can be implemented, to prevent electrical connection between the plurality of active pillars 20 and the plurality of word lines 30, and yield of the semiconductor structure can be improved. A material of the dielectric layer 40 includes silicon oxide or silicon nitride, but is not limited thereto.

An air gap 41 is provided in the dielectric layer 40 positioned between the adjacent word lines 30 to reduce the dielectric constant of the dielectric layer 40 positioned between the adjacent word lines 30, thereby reducing the parasitic capacitance between the adjacent word lines, and improving the performance of the semiconductor structure.

In this embodiment, the dielectric constant of the dielectric layer 40 positioned between the adjacent word lines 30 is reduced while a pitch between the adjacent word lines 30 is decreased, thereby maximally reducing the parasitic capacitance between the adjacent word lines 30, reducing interference of the parasitic capacitance on the semiconductor structure, and improving stability of data input/output (I/O) transmission of the semiconductor structure.

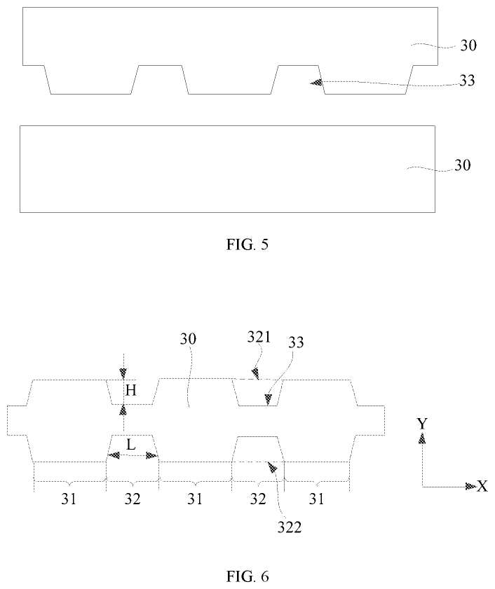

In a possible embodiment, referring to FIG. 6, each of the word lines 30 includes a plurality of first segments 31 and a plurality of second segments 32, where the plurality of first segments 31 and the plurality of second segments 32 are arranged alternately and connected to each other.

The first segments 31 surround the active pillars 20 and form the transistor with the active pillars 20. The second segments 32 connect adjacent first segments 31, such that the plurality of second segments 32 interconnect the plurality of first segments 31 to form the word lines 30 extending along the first direction.

The groove 33 may be provided in a first segment 31 or a second segment 32. For example, the groove 33 may be provided in the second segment 32. In this way, in one aspect, damage to the active pillars may be avoided, such that yield of the semiconductor structure is increased. In another aspect, an arrangement location of the groove 33 is kept away from the active pillar, such that a depth of the groove 33 may be set to be as large as possible. In this way, the pitch between the adjacent word lines 30 at a location where the groove 33 is positioned may be increased, thereby reducing the parasitic capacitance generated between the adjacent word lines 30.

In this embodiment, the groove 33 is at least provided in one second segment 32. In an example, there is one groove 33, and the groove 33 may be provided in one of second segments 32. In yet another example, there are a plurality of grooves 33, and number of the grooves 33 is smaller than number of the second segments 32, such that the grooves 33 may be provided in part of the second segments 32. In another example, the number of the grooves 33 is equal to the number of the second segments 32, and one groove 33 is provided in each second segment 32. In this way, the parasitic capacitance generated between the adjacent word lines 30 can be maximally reduced, thereby reducing the interference of the parasitic capacitance on the semiconductor structure, and improving the stability of data I/O transmission of the semiconductor structure.

In this embodiment, the groove 33 may be provided in one surface of the second segment 32 or may be provided in two surfaces of the second segment 32 simultaneously. For example, in the second direction Y, the second segment 32 has a first surface 321 and a second surface 322 arranged opposite to each other. By taking an orientation shown in FIG. 6 as an example, the first surface 321 is an upper surface of the second segment 32, and the second surface 322 is a lower surface of the second segment 32.

The groove 33 is respectively provided in the first surface 321 and the second surface 322, and the groove 33 penetrates through the word line 30 along the direction perpendicular to the substrate 10, such that the groove 33 becomes a through groove penetrating through the word line 30. In this way, the pitch between the word line 30 and any word line 30 adjacent thereto is increased, thus it is ensured that only smaller parasitic capacitance is provided between the adjacent word lines 30, and thus the performance of the semiconductor structure is improved.

It should be noted that there may be one or two grooves 33 provided on the second segment 32. When there are two grooves 33, the two grooves 33 are spaced on the second segment 32.

Referring to FIGS. 1, 7, and 8, a section parallel to the substrate 10 is taken as a cross section, and the cross section of the groove 33 may be in regular shape. For example, a shape of the cross section of the groove 33 includes a rectangle, a trapezoid, or a semicircle. The shape of the cross section of the groove 33 may also be an irregular shape. For example, the shape of the cross section of the groove 33 is a zigzag.

When the shape of the cross section of the groove 33 is the regular shape, fabrication of the groove 33 may be facilitated, and fabrication difficulty of the word line 30 may be reduced.

In a possible embodiment, when the shape of the cross section of the groove 33 is the trapezoid, a pitch between two side walls of the groove 33 gradually decreases in a direction pointing from a groove opening to a groove bottom of the groove 33. That is, the shape of the cross section of the groove 33 is an inverted trapezoid. In this way, on the premise of reducing the parasitic capacitance between the adjacent word lines, excessive reduction of the width of the word line is avoided, such that increasing a resistance of the word line is avoided, and stability of transmission of a signal on the word line is improved.

The pitch between the two side walls of the groove 33 in this embodiment may be understood as L in FIG. 6.

In a possible embodiment, along the extending direction perpendicular to the word line 30, that is, along the Y direction shown in FIG. 6, a ratio of a depth H of the groove 33 to the width of the word line 30 is between 1/10 and 1/4.

When the ratio of the depth of the groove 33 to the width of the word line 30 is less than 1/10, the depth of the groove 33 is too small. In this case, the parasitic capacitance formed between the adjacent word lines 30 cannot be effectively reduced, and the performance of the semiconductor structure cannot be improved.

When the ratio of the depth of the groove 33 to the width of the word line 30 is greater than 1/4, the depth of the groove 33 will be too large, such that the width of the word line 30 is reduced, and the resistance of the word line 30 is increased, thereby reducing stability of data signal transmission of the semiconductor structure.

Therefore, in this embodiment, the ratio of the depth of the groove 33 to the width of the word line 30 is between 1/10 and 1/4. In one aspect, the pitch between the adjacent word lines 30 may be increased, and the parasitic capacitance generated between the adjacent word lines 30 is reduced, thereby reducing the interference of the parasitic capacitance, and improving the stability of data I/O transmission of the semiconductor structure.

In another aspect, the width of the word line 30 will not be reduced excessively, and thus stability and timeliness of data signal transmission of the semiconductor structure can be improved.

In a possible embodiment, the air gap 41 is provided in the dielectric layer 40 between the first segments 31. In this way, it may be prevented that the groove 33 is provided on the first segment 31, thereby avoiding increasing the resistance of the word line 30. Meanwhile, the dielectric constant of the air gap 41 is smaller than that of the dielectric layer 40, such that the dielectric constant of the dielectric layer 40 positioned between the adjacent first segments 31 is reduced, thereby reducing the parasitic capacitance generated between the adjacent word lines 30, and improving the performance of the semiconductor structure.

In a possible embodiment, a section perpendicular to the substrate 10 is taken as a longitudinal section, and a shape of the longitudinal section of the air gap 41 is an ellipse. It should be noted that the shape of the cross section of the air gap 41 may also be another regular shape. For example, the shape of the cross section of the air gap 41 may also be a rectangle, a square, a trapezoid, or a circle, such that formation of the air gap 41 is facilitated. Of course, under the condition of different process parameters, the shape of the cross section of the air gap 41 may also be other irregular shapes.

In a possible embodiment, with continued reference to FIG. 2, along the direction perpendicular to the substrate 10, the top surface of the air gap 41 is flush with or higher than the top surface of the word line 30. That is, all the air gaps 41 are positioned in the dielectric layer 40 between the adjacent word lines 30, or a part of the air gaps 41 are positioned in the dielectric layer 40 between the adjacent word lines 30.

In a possible embodiment, along the extending direction perpendicular to the word line 30, a width of the air gap 41 ranges from 5 nm to 10 nm.

When the width of the air gap 41 is less than 5 nm, the width of the air gap 41 is too small, which causes volume of the air gap 41 to be too small, such that it is difficult to reduce the dielectric constant of the dielectric layer 40 positioned between the adjacent word lines 30.

When the width of the air gap 41 is greater than 10 nm, the width of the air gap 41 is too large, which causes the width of the dielectric layer 40 positioned between the adjacent word lines 30 to be too small, or even causes occurrence of electrical connection between the adjacent word lines 30, thereby reducing the yield of the semiconductor structure.

In this way, in this embodiment, the width of the air gap ranges from 5 nm to 10 nm. In one aspect, the dielectric constant of the dielectric layer 40 positioned between the adjacent word lines 30 may be reduced, and the parasitic capacitance generated between the adjacent word lines 30 is reduced, thereby reducing the interference of the parasitic capacitance, and improving the stability of data I/O transmission of the semiconductor structure.

In another aspect, the width of the dielectric layer 40 positioned between the adjacent word lines 30 is not reduced excessively, such that electrical connection between the adjacent word lines 30 is prevented, and the yield of the semiconductor structure is increased.

In a possible embodiment, the semiconductor structure further includes a plurality of bit lines 50, where the plurality of bit lines 50 are arranged in the substrate 10 at intervals along the first direction, and each of the bit lines 50 extends along the second direction to connect all the active pillars 20 positioned in the same second direction.

During formation of the bit lines 50, a conductive layer of a certain thickness may be deposited on the substrate 10, then the conductive layer is patterned to remove part of the conductive layer, and a remaining portion of the conductive layer forms the plurality of bit lines, where a material of the bit lines 50 may include silicon germanide. Compared with a technical solution where the bit line is made of titanium nitride and tungsten in the related technologies, the resistance of the bit line 50 may be reduced by means of higher mobility of germanium to improve the performance of the semiconductor structure. In addition, the bit line 50 in this embodiment is formed together with fabrication of the active pillars 20, such that fabrication processes of the semiconductor structure can be simplified.

The semiconductor structure further includes a plurality of capacitors 60, and the plurality of capacitors 60 are in one-to-one correspondence with the plurality of active pillars 20 and are correspondingly arranged on the plurality of active pillars 20. That is, number of the capacitors 60 is equal to that of the active pillars 20, and one capacitor 60 is disposed on one active pillar 20.

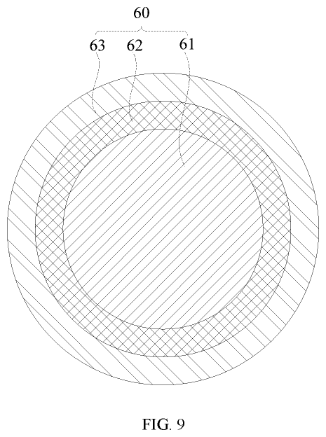

Referring to FIG. 9, the capacitor 60 is of a columnar structure, comprising a columnar first electrode 61 and a first dielectric layer 62 and a second electrode 63 sequentially surrounding the first electrode 61, where the first electrode 61 is electrically connected to the active pillar 20. In this way, a volume of the first electrode 61 can be increased, strength of the first electrode 61 can be enhanced, and difficulty of fabricating the first electrode 61 can be reduced, collapse of the first electrode 61 can be prevented, and the yield of the semiconductor structure can be improved.

It should be noted that in this example, a material of the first electrode 61 and a material of the second electrode 63 are the same, for example, tungsten or titanium nitride, but not limited thereto.

A material of the first dielectric layer 62 may be a high-k dielectric material. For example, the dielectric material may include at least one of ZrOₓ, HfOₓ, ZrTiOₓ, RuOₓ, SbOₓ, and AlOₓ. That is, a material of the first dielectric layer 62 may be one of the above materials, or may be a mixture of the above materials. In some embodiments, the first dielectric layer 62 may be a stacked structure. For example, the first dielectric layer 62 may include a three-layer structure, and materials of the three-layer structure are zirconium oxide-aluminium oxide-zirconium oxide, and the first dielectric layer 62 may include a zirconium oxide layer, an aluminum oxide layer and a zirconium oxide layer which are stacked in sequence.

In this embodiment, by limiting the material of the first dielectric layer 62, storage capacity of the capacitor structure subsequently formed can be increased, and the performance of the semiconductor structure can be improved.

In this embodiment, one end of the active pillar 20 is connected to the bit line and other end of the active pillar 20 is connected to the capacitor 60. In this way, data can be written into the capacitor 60 through the bit line 50, or the data in the capacitor 60 can be read through the bit line 50, to implement a read function of the semiconductor structure.

In this embodiment, a fabrication process of the capacitor 60 may be as follows. A plurality of capacitor holes may be formed in the dielectric layer 40, each of the capacitor holes exposes at least the top surface of each active pillar 20, and then a capacitor 60 is formed in each capacitor hole by means of a deposition process.

In a possible embodiment, with continued reference to FIG. 2, the active pillar includes a channel region 21, a source region 22 and a drain region 23, where the source region 22 and the drain region 23 are respectively arranged on two sides of the channel region 21. From top to bottom, a region between the top of the active pillar 20 and a first dashed line is the source region 22, a region between the first dashed line and a second dashed line is the channel region 21, and a region between the second dashed line and the bottom of the active pillar 20 is the drain region 23.

The source region 22 and the drain region 23 have the same type of doped ions, and have different types of doped ions from the channel region 21. In an example, the doped ions of the source region 22 and the drain region 23 may include N-type ions, for example, elements in the VA main group in the periodic table of elements, such as phosphorus (P). The doped ions of the channel region 21 may include P-type ions, for example, the P-type ions may include IIIA group element ions such as boron (B) or gallium (Ga), such that the active pillar is formed into an NPN type. In another example, the doped ions of the source region 22 and the drain region 23 may include P-type ions, for example, the P-type ions may include the IIIA group element ions such as boron (B) or gallium (Ga). The doped ions of the channel region 21 may include N-type ions, e.g., elements in VA group of the periodic table of elements, such as phosphorus (P), such that the active pillar 20 is formed into a PNP type.

In this embodiment, the fabrication process of the active pillars 20 may be performed in the following manners. In an example, an active layer may be formed on the substrate 10, and then a plurality of first trenches and a plurality of second trenches may be formed in the active layer by means of etching. The plurality of first trenches are arranged at intervals along the second direction and extend along the first direction. The plurality of second trenches are arranged at intervals along the first direction and extend along the second direction. The active layer is separated into a plurality of columnar structures by the plurality of first trenches and the plurality of second trenches.

Next, the columnar structures may be doped by means of an ion implantation process or an ion diffusion process to form the active pillars 20.

In another example, a first active layer, a second active layer and a third active layer stacked may be formed on the substrate 10, where the first active layer and the third active layer have the same type of doped ions, and are configured to form the source region and the drain region subsequently. The second active layer has different types of doped ions from the first active layer, and is configured to form the channel region subsequently.

Next, the first active layer, the second active layer and the third active layer are patterned to form, on the substrate 10, the plurality of active pillars 20 arranged in an array.

It should be noted that, in this example, the first active layer, the second active layer and the third active layer may be fabricated by means of an in-situ doping process. For example, a silicon layer is formed on the substrate 10 by means of an epitaxial growth process. Meanwhile, N-type ions such as phosphorus ions are introduced into a deposition device during the growth process, such that the N-type ions are doped into the silicon layer to form the first active layer.

A portion of the word lines 30 surround the channel region 21. That is, the first segment 31 surrounds the channel region 21, such that the first segment 31 and the active pillar 20 form the transistor. A voltage of the first segment 31 is employed to control connection or disconnection between the source region 22 and the drain region 23 of the active pillar 20.

A gate oxide layer 70 is disposed between the word line 30 and the channel region 21, and the gate oxide layer 70 has a higher dielectric constant to increase charge storage capability of the gate oxide layer 70 and prevent electrons or a small number of current carrier generated by the word line 30 from entering the drain region 23 of the active pillar 20 through the gate oxide layer 70, thereby reducing gate-induced drain leakage current and improving the performance of the semiconductor structure.

One of the source region 22 and the drain region 23 is connected to the capacitor and other one of the source region 22 and the drain region 23 is connected to the bit line In one example, the source region 22 is connected to the capacitor 60, and the drain region 23 is connected to the bit line 50. In another example, the source region 22 is connected to the bit line 50, and the drain region 23 is connected to the capacitor 60.

When a peripheral circuit applies a high voltage to the word line 30, the word line 30 applies the voltage to the channel region 21, to control the connection between the source region 22 and the drain region 23 of the active pillar 20, thereby implementing access capabilities of the semiconductor structure.

The embodiments of the present disclosure further provide a semiconductor memory, which includes the semiconductor structure in the above-mentioned embodiments. Structures and beneficial effects of the semiconductor structure have been described in detail in the above-mentioned embodiments, and thus are not elaborated herein in this embodiment.

The embodiments or the implementation manners in this specification are described in a progressive manner. Each of the embodiments is focused on difference from other embodiments, and cross reference is available for identical or similar parts among different embodiments.

In the descriptions of this specification, descriptions of reference terms “one embodiment”, “some embodiments”, “an exemplary embodiment”, “an example”, “one example”, or “some examples” are intended to indicate that features, structures, materials, or characteristics described with reference to the embodiment or example are included in at least one embodiment or example of the present disclosure.

The schematic representation of the above terms throughout this specification does not necessarily refer to the same embodiment or example. Furthermore, the features, structures, materials, or characteristics set forth may be combined in any suitable manner in one or more embodiments or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A semiconductor structure, comprising:
a substrate; and
a plurality of active pillars spaced on the substrate, each of the plurality of active pillars extending along a direction perpendicular to the substrate;
a plurality of word lines spaced on the substrate along a second direction, each of the plurality of word lines extending along a first direction, wherein the first direction intersects with the second direction, each of the plurality of word lines being connected to a given one of the plurality of active pillars positioned in the first direction; and in any adjacent two of the plurality of word lines, a groove is provided on a surface of at least one of the two adjacent word lines towards other one of the two adjacent word lines, the groove penetrating through the word line along the direction perpendicular to the substrate; and
a dielectric layer arranged on the substrate and covering the plurality of active pillars and the plurality of word lines; wherein an air gap is provided in the dielectric layer positioned between adjacent two of the plurality of word lines.

2. The semiconductor structure according to claim 1, wherein each of the plurality of word lines comprises a plurality of first segments and a plurality of second segments connected sequentially and arranged alternately; the plurality of first segments surround the plurality of active pillars; and
the groove is provided in at least one of the plurality of second segments, the air gap being arranged in the dielectric layer between adjacent two of the plurality of first segments along the second direction.

3. The semiconductor structure according to claim 2, wherein in the second direction, each of the plurality of second segments has a first surface and a second surface arranged opposite to each other; and the groove is respectively provided in the first surface and the second surface.

4. The semiconductor structure according to claim 1, wherein a section parallel to the substrate is taken as a cross section, a shape of the cross section of the groove comprising a rectangle, a trapezoid, or a semicircle.

5. The semiconductor structure according to claim 4, wherein when the shape of the cross section of the groove is the trapezoid, a pitch between two side walls of the groove gradually decreases in a direction pointing from a groove opening to a groove bottom of the groove.

6. The semiconductor structure according to claim 1, wherein along an extension direction perpendicular to a given one of the plurality of word lines, a ratio of a depth of the groove to a width of the given word line is between 1/10 and 1/4.

7. The semiconductor structure according to claim 1, wherein along the direction perpendicular to the substrate, a top surface of the air gap is flush with or higher than a top surface of a given one of the plurality of word lines.

8. The semiconductor structure according to claim 6, wherein along the extension direction perpendicular to the given word line, a width of the air gap ranges from 5 nm to 10 nm.

9. The semiconductor structure according to claim 7, wherein a section perpendicular to the substrate is taken as a longitudinal section, a shape of the longitudinal section of the air gap being an ellipse.

10. The semiconductor structure according to claim 1, further comprising a plurality of bit lines spaced in the substrate along the first direction, each of the plurality of bit lines extending along the second direction, and each of the plurality of bit lines being connected to the plurality of active pillars positioned in the same second direction.

11. The semiconductor structure according to claim 10, further comprising a plurality of capacitors, the plurality of capacitors being in one-to-one correspondence with the plurality of active pillars and being correspondingly arranged on the plurality of active pillars.

12. The semiconductor structure according to claim 11, wherein each of the plurality of active pillars comprises a channel region and a source region and a drain region respectively arranged on two sides of the channel region;
part of the plurality of word lines surround the channel region; and
one of the source region and the drain region is connected to a given one of the plurality of capacitors, other one of the source region and the drain region being connected to a given one of the plurality of bit lines.

13. The semiconductor structure according to claim 12, wherein a gate oxide layer is arranged between the given word line and the channel region.

14. The semiconductor structure according to claim 12, wherein the given capacitor is of a columnar structure, the given capacitor comprising a columnar first electrode, a first dielectric layer and a second electrode sequentially surrounding the first electrode, and the first electrode being in electrical contact with a given one of the plurality of active pillars.

15. A semiconductor memory, at least comprising the semiconductor structure according to claim 1.

16. A semiconductor structure, comprising:
a substrate;
an active pillar, the active pillar being arranged at intervals on the substrate; and
a word line, the word line surrounding a side of the active pillar;
wherein a first part of the word line surrounding the side of the active pillar is wider than a second part of the word line.

17. The semiconductor structure according to claim 16, further comprising an air gap, the air gap being configured between adjacent two active pillars.

18. The semiconductor structure according to claim 17, wherein a top surface of the air gap is flush with or higher than a top surface of the word line.

19. The semiconductor structure according to claim 16, further comprising an air gap, the air gap being configured between adjacent two word lines.

20. The semiconductor structure according to claim 19, wherein a top surface of the air gap is flush with or higher than a top surface of the word line.
